(19) United States
(12) Patent Application Publication
(10) Pub. No.: US 2014/0362503 A1
(43) Pub. Date: Dec. 11, 2014

(54) SERVER CABINET

(71) Applicant: HON HAI PRECISION INDUSTRY CO., LTD., New Taipei (TW)

(72) Inventors: MING-HSUAN HO, New Taipei (TW); CHO-HAO WANG, New Taipei (TW)

(21) Appl. No.: 14/296,414

(22) Filed: Jun. 4, 2014

(30) Foreign Application Priority Data
Jun. 6, 2013 (TW) 102120075

(51) Int. Cl. H05K 7/14

(52) U.S. Cl. CPC H05K 7/1489
USPC 361/679.02

(57) ABSTRACT

A server cabinet includes a rack, a server slidably mounted in the rack, and an ejecting member attached to the rack and the server. The ejecting member is made of shape-memory alloy and can be compressed by the server under normal operating conditions. When the server is on fire, the transformation temperature of the ejecting member is greater than a first temperature, the ejecting member restores and ejects the server out of the rack.

### FIELD

The present disclosure relates to server cabinet construction.

### BACKGROUND

A plurality of servers is mounted in a server cabinet. When the temperature of electronic components in the servers is too high, many negative effects can occur, including a fire. If this occurs the power of all the servers should be turned off.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded view of an embodiment of a server cabinet.

FIG. 2 is an assembled view of the server cabinet of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

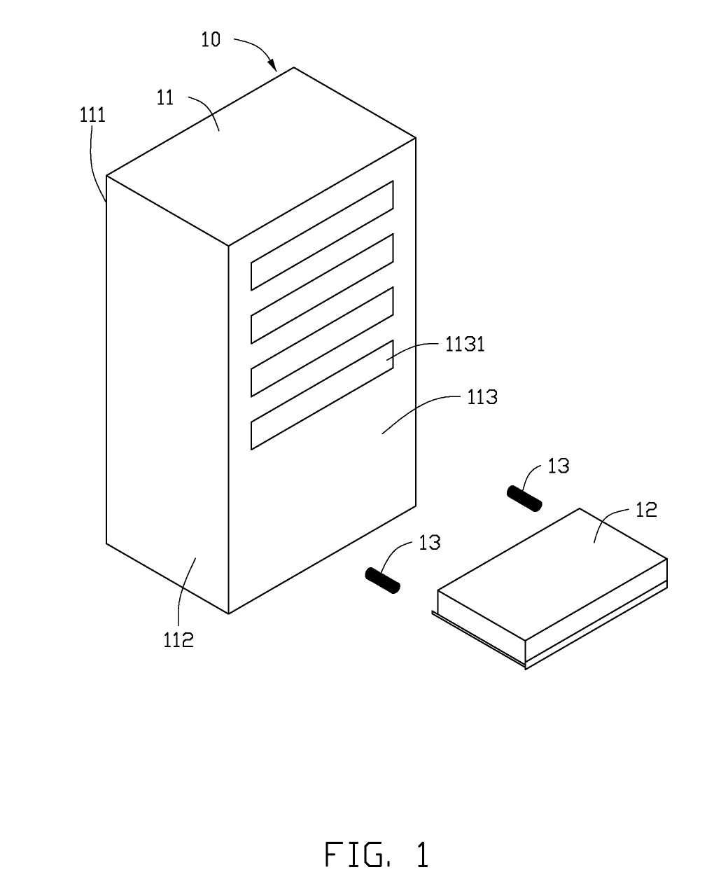

FIG. 1 illustrates an embodiment of a server cabinet 10. The server cabinet 10 comprises a rack 11, a plurality of servers 12, and a plurality of ejecting members 13.

The rack 11 comprises a front wall 113, a rear wall 111, and two sidewalls 112 connected between opposite sides of the front wall 113 and the rear wall 111. The front wall 113 defines a plurality of openings 1131, arranged orderly on the front wall 113.

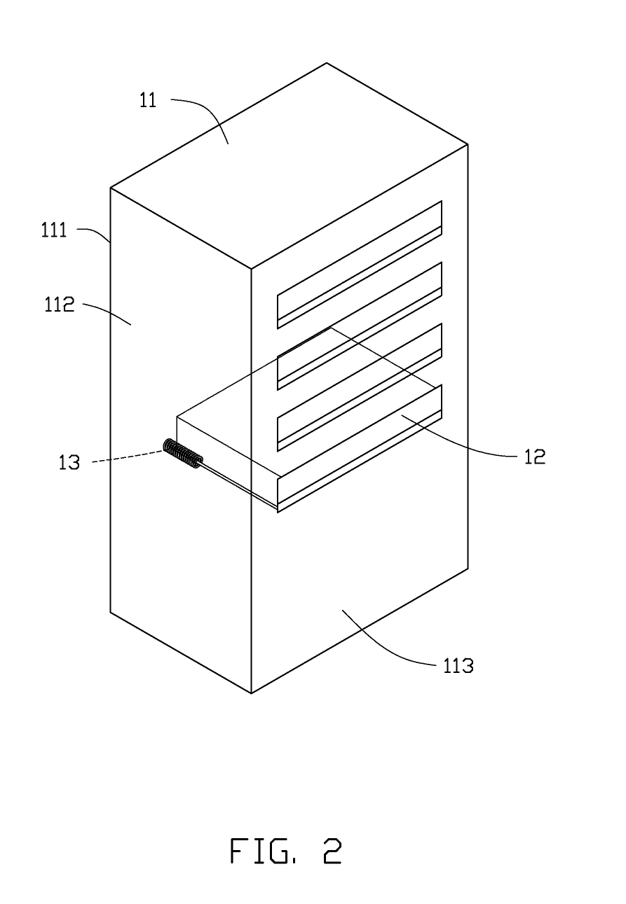

FIG. 2 illustrates the servers 12 are slidably mounted into the rack 11 from the openings 1131. Two of the ejecting members 13 are mounted between each server 12 and the rear wall 111. A front end of each ejecting member 13 is attached to a rear side of a corresponding server 12, so that the ejecting member 13 can be transferred heat from the server 12. A rear end of the ejecting member 13 is attached to the rear wall 111.

When the servers 12 are installed in the rack 11, the ejecting members 13 can be, if they are not already, compressed by the servers 12. The ejecting members 13 are made of shape-memory alloy, and are spring-shaped. Therefore, each ejecting member 13 has a transformation temperature, when the temperature of the ejecting member 13 is greater than the transformation temperature, the ejecting member 13 restores to a predetermined size by expanding. In some embodiments, the ejecting member 13 is linear. In the embodiments where the ejecting member 13 is shaped like a spring, the shape enables for there to be more of the shape memory alloy to be present in the space and have a greater ejecting effect. The transformation temperature of the ejecting members 13 is greater than a normal working temperature of the servers 12, and the transformation temperature of the ejecting members 13 is less than a temperature that would start a fire in the servers 12.

When a fire starts in one of the servers 12, the temperature of the server 12, and two of the ejecting members 13 attached to the server 12, is greater than the transformation temperature of the ejecting members 13. The two ejecting members 13 restore to eject the server 12 out of the rack 11, so that other servers 12 can still work normally.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A server cabinet, comprising:
a rack;
a server slidably mounted in the rack; and
an ejecting member attached to the rack and the server, the ejecting member being made of shape memory alloy;
wherein a transformation temperature of the ejecting member is greater than a normal working temperature of the server, and the transformation temperature of the ejecting member is less than a temperature that would start a fire in the server; and when the temperature of the ejecting member is greater than the transformation temperature, the ejecting member restores to eject the server out of the rack.

2. The server cabinet of claim 1, wherein the rack comprises a front wall and a rear wall, the front wall defines an opening for the server to enter, the ejecting member is attached to the rear wall and a rear side of the server.

3. The server cabinet of claim 1, wherein the ejecting member is spring-shaped.
